(19) United States
(12) Patent Application Publication
(10) Pub. No.: US 2025/0067793 A1
(43) Pub. Date: Feb. 27, 2025

(54) ELECTRONIC DEVICE

(71) Applicant: InnoLux Corporation, Miao-Li County (TW)

(72) Inventors: Chia-Hao TSAI, Miao-Li County (TW); Yi-Shiuan CHERNG, Miao-Li County (TW)

(73) Assignee: InnoLux Corporation, Miao-Li County (TW)

(21) Appl. No.: 18/788,029

(22) Filed: Jul. 29, 2024

(30) Foreign Application Priority Data
Aug. 21, 2023 (CN) 202311049046.8

(51) Int. Cl. G01R 31/28; H01L 23/528; H01L 27/15

(52) U.S. Cl. CPC G01R 31/2825; H01L 23/5283; H01L 27/156

(57) ABSTRACT

An electronic device includes a panel. The panel includes a substrate, and a plurality of signal lines and a test circuit are disposed on the substrate. The test circuit includes a first switch device and a second switch device that are electrically connected to a same switch signal line. A first conductive component is connected between the first switch device and one of the signal lines. A second conductive component is connected between the second switch device and another one of the signal lines. The first conductive component and the second switch device are at least partially overlapped.

### BACKGROUND OF THE DISCLOSURE

### 1. Field of the Disclosure

The present disclosure relates to an electronic device, in particular an electronic device that includes a panel.

### 2. Description of the Prior Art

Display panels are widely used in a variety of consumer electronics, such as computer screens, mobile phones, TVs, etc. In order to improve the yield of the display panel and ensure the shipping quality, test circuits for testing the array of the display panel and detect the electrical characteristics of the pixel array are usually arranged in the non-display region such as the peripheral region of the panel. However, current high PPI (pixel per inch) products with narrow bezel design are suffered from yield loss due to insufficient area of the peripheral region for a complete test circuit to test the entire pixel array. Therefore, a novel test circuit design to meet the needs of narrow bezel products is still earnestly required in the field.

### SUMMARY OF THE DISCLOSURE

Embodiments of the present disclosure provide an electronic device that includes a panel. The panel of the electronic device includes a substrate, and a plurality of signal lines and a test circuit are disposed on the substrate. The test circuit includes a first switch device and a second switch device that are electrically connected to a same switch signal line. A first conductive component is connected between the first switch device and one of the signal lines. A second conductive component is connected between the second switch device and another one of the signal lines. The first conductive component and the second switch device are at least partially overlapped.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic plan view of a portion of a panel of an electronic device according to an embodiment of the present disclosure, showing a layout of a test circuit unit.

FIG. 2 shows schematic cross-sectional views of different positions of a panel of an electronic device according to an embodiment of the present disclosure.

FIG. 3 is an equivalent circuit diagram of a test circuit unit according to an embodiment of present disclosure.

FIG. 4 is a schematic plan view of a portion of a panel of an electronic device according to an embodiment of the present disclosure.

FIG. 5 is a schematic diagram showing an arrangement of circuit blocks of a first gate driving circuit according to an embodiment of the present disclosure.

FIG. 6 is a schematic diagram showing an arrangement of circuit blocks of a second gate driving circuit according to an embodiment of the present disclosure.

FIG. 7 is a schematic plan view of a portion of a panel of an electronic device according to an embodiment of the present disclosure.

FIG. 8 is a schematic plan view of a portion of a panel of an electronic device according to an embodiment of the present disclosure.

FIG. 9 is a schematic plan view of a portion of a panel of an electronic device according to an embodiment of the present disclosure.

FIG. 10 is a schematic plan view of a portion of a panel of an electronic device according to an embodiment of the present disclosure.

### DETAILED DESCRIPTION

The present disclosure may be understood by referring to the detailed description below and the accompanying drawings. It is noted that, for purposes of illustrative clarity and being easily understood by the readers, various drawings of this disclosure show a portion of the electronic device, and certain components in various drawings may not be drawn to scale. In addition, the number and dimension of each component shown in drawings are only illustrative and are not intended to limit the scope of the present disclosure. Other embodiments may be utilized and structural, logical, and electrical changes may be made without departing from the scope of the present disclosure.

Certain terms are used throughout the specification and following claims to refer to particular components. As one skilled in the art will understand, electronic equipment manufacturers may refer to a component by different names. This document does not intend to distinguish between components that differ in name but not function. In the following specification and in the claims, the terms “include”, “comprise” and “have” are used in an open-ended fashion, and thus should be interpreted to mean “include, but not limited to . . . ”.

It should be understood that when a component or a layer is said to be “on another component or another layer” or “connected to another component or another layer”, it may be directly on or directly connected to another component or another layer, or it may be indirectly on or indirectly connected to another component or another layer for having intervening components or layers presented therebetween. On the other hand, when a component or a layer is referred to as being “directly on” or “directly connected to” another element or layer, there is no intervening components or layers presented.

Similarly, when a component is said to be “coupled to another component or variant” or “electrically coupled to another component or variant”, it may be directly coupled to another component or variant, or it may be indirectly coupled (such as electrically coupled) to another component or variant through one or more intervening components.

Spatially spatial relative terms, such as “lower”, “bottom”, “upper” or “top” and the like, used in the following embodiments are used to describe the position of one component relative to another, and are intended to include different orientations of the device in addition to those shown in the drawing. For example, if the device in the figures is turned over, components described as “lower” would then be oriented to be “upper” components. That is, the spatial relationship of the components is described according to the particular orientation of the drawings.

The terms “first”, “second”, “third” and the like may be used in the specification and following claims for the convenience of discriminating various components in the specification or claims. However, these terms are not used to limit these components and these components may be denominate in any convenient way. These terms do not indicate any order of the components, and do not represent any order of a component to another component or a sequence of the manufacturing steps. Furthermore, the claims may use terminology different from that used in the specification, and may be nominated as “first”, “second”, “third” and the like in accordance with the order in which the components are declared in the claim. For example, a “first component” in the specification may be nominated as a “second component” in the claims.

The terms “about”, “approximately”, “substantial” and the like generally means within 10%, or within 5%, or within 3%, or within 2%, or within 1%, or within 0.5% of a given value or range. Unless indicated to the contrary, the numerical ranges, amounts, values and percentages given in the disclosure should be implied in all instances by the term “about”, “approximately”, or “substantial”, and are approximations that can vary as desired.

The electronic device disclosed herein may include display devices, backlit devices, antenna devices, sensing devices, or splicing devices, but are not limited thereto. The display devices include conventional display devices and special display devices such as splicing display devices, bendable or flexible display devices, but are not limited thereto. The antenna devices may be liquid crystal antenna devices or non-liquid crystal antenna devices. The sensing devices may be capacitive, photosensitive, thermal or acoustic wave sensing devices, but are not limited thereto. The splicing devices may be splicing display devices or splicing antenna devices, but are not limited thereto. It should be noted that, the electronic device may be any combination of the devices described above, but is not limited thereto. Furthermore, the electronic device may have a rectangular shape, a circular shape, a polygonal shape, a shape with curved edges, or other suitable shapes. The electronic device may include a peripheral system to properly function as a display device, an antenna devices, a wearable device (such as augmented reality or virtual reality wearable device), an automotive assembly (such as windshield), or a splicing device. In the following, an electronic device including a panel is used as an example to elaborate the content of the disclosure, and should not be taken as a limitation to the disclosure.

The panel of the electronic device may be a display panel used to constitute a display equipment. The electronic device may include any suitable display medium such as liquid crystal, light emitting diode, fluorescence, phosphor, or a combination thereof, but is not limited thereto. The electronic device may be a non-self-luminous display equipment such as a liquid crystal display (LCD), or a self-luminous display equipment such as an organic light emitting diode (OLED) display, an inorganic light emitting diode (LED) display, a mini LED display, a micro LED display, a quantum dot light emitting diode (QLED) display, or an electro-phoretic display (EPD), but is not limited thereto. The electronic device may display images and pictures.

In the following description, the edges of the display region or the cutting edges of the substrate parallel to the extending directions of the data lines or the scan lines are referred to as “flat edges”. Other edges that are not parallel to the “flat edges” or extend along directions different from the extending directions of the data lines or the scan lines are referred to as “bevel edges”.

It should be noted that the following embodiments may be substituted, recombined and mixed with features of each other without departing from the scope of the present disclosure.

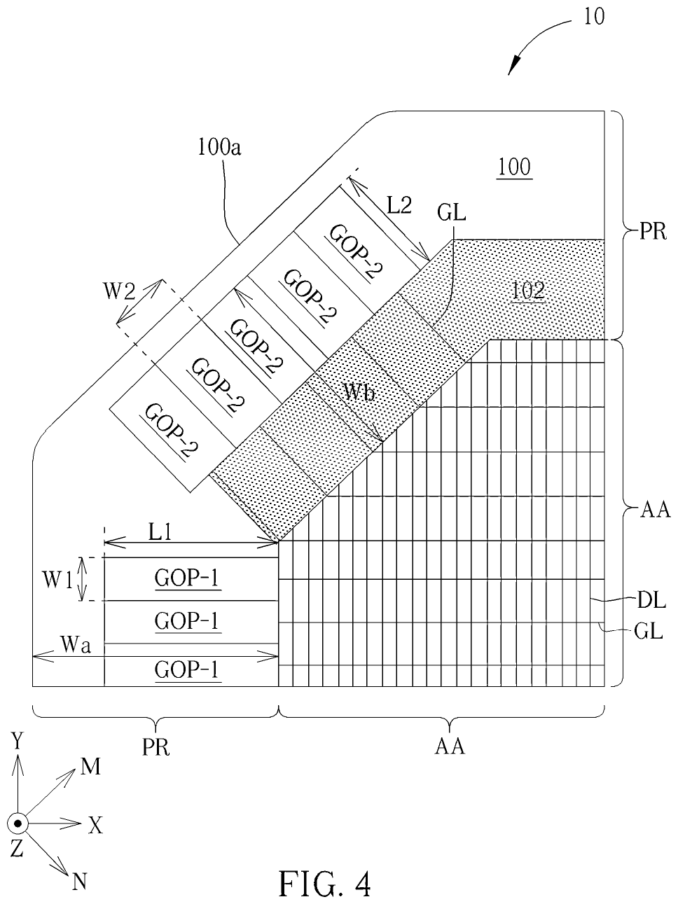

Please refer to FIG. 4, which is a schematic plan view of a portion of a panel 10 according to an embodiment of the present disclosure. The surface of the panel 10 extends along the plane defined by the X direction and the Y direction. The X direction and the Y direction are perpendicular to each other. The Z direction is perpendicular to the surface of the panel 10. The M direction and the N direction are parallel to the surface of the panel 10 and are different from the X direction and the Y direction. In some embodiments, the M direction and the N direction are perpendicular to each other.

As shown in FIG. 4, the panel 10 includes a display region AA and a peripheral region PR next to at least a side of the display region AA. The display region AA includes a pixel array that display images or pictures. A plurality of signal lines extend through the display region AA along the X direction or the Y direction, and are electrically connected to each pixel unit to control the operation of each pixel unit. To simplify the drawing, only the data lines DL and the scan lines GL are schematically shown in FIG. 4. The data lines DL extend along the Y direction and arranged in parallel along the X direction. The scan lines GL extend along the X direction and arranged in parallel along the Y direction. The regions between each pair of neighboring data lines DL and each pair of neighboring scan lines GL may be referred to as where the pixel units locate.

The peripheral region PR includes peripheral circuits or electronic components used to control the display region AA to display images or test the yield of the display region AA. For example, the peripheral region PR may include gate driving circuits, chip bonding circuits, fan-out circuits, demultiplexers, panel circuits, FPC bonding circuits, test circuits, reset circuits, compensation control circuits, initialization circuits, power lines, ground lines, clock signal lines, capacitors, inductors, or a combination thereof, but is not limited thereto. The gate driving circuits, known as Gate on Array (GOA) or Gate on Panel (GOP), are used to generate gate driving signals for the pixels of the display region AA. The chip bonding circuits are used to bond driving chips (ICs). The fan-out circuits are used to realize the interconnection between the driving chips and the data lines in the display region AA. The demultiplexers are used to split the output of the driving chip into corresponding data lines. The panel circuits are used to interconnect the wiring around the panel. The FPC bonding circuits are bonding regions for flexible circuit boards to connect the circuit boards. The test circuits are electrically connected to the display region AA, providing test signals to the display region AA through interconnecting traces to test the electrical characteristics and yields of the pixels.

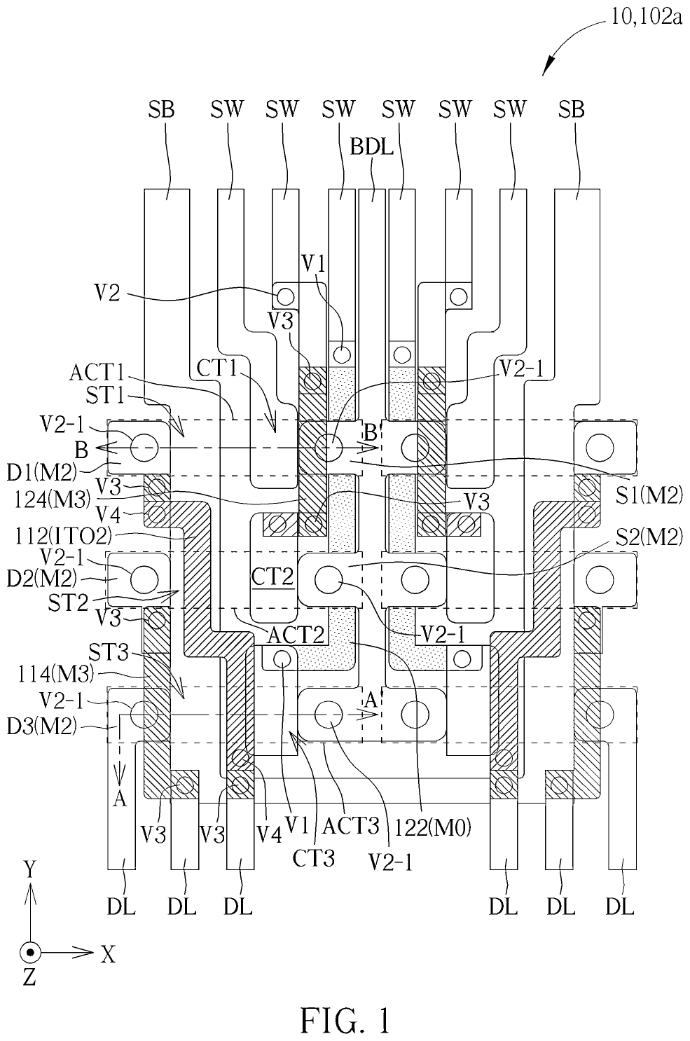

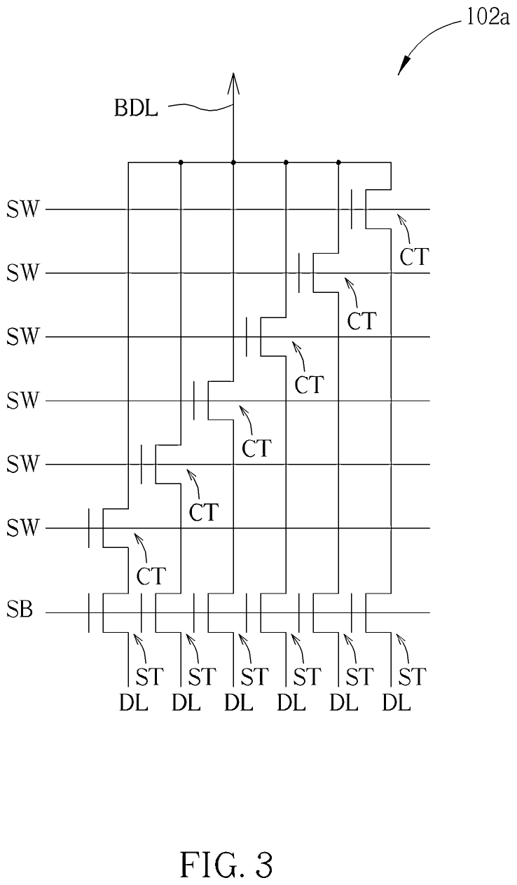

To simplify the drawing, only some the gate driving circuits (such as the first gate driving circuits GOP-1 and the second gate driving circuits GOP-2) and some of the test circuit 102 are shown in FIG. 4. In more detail, the test circuit 102 is arranged along a flat edge of the display region AA where the data lines DL extend out from the display region AA to facilitate the electrical connection with the data lines DL. In some embodiments, the test circuit 102 may be consists of a plurality of test circuit units 102a (refer to FIG. 1 and FIG. 3) to shorten the trace length and improve space utilization. The gate driving circuits (such as the first gate driving circuits GOP-1) are arranged along another flat edge of the display region AA where the scan lines GL extend out from the display region AA to facilitate the electrical connection with the scan lines GL. In some embodiments, when the display region AA includes a bevel edge (such as the bevel edge along the M direction as shown in FIG. 4) and therefore some of the data lines DL and the scan lines GL concurrently extend out from the bevel edge, the test circuit 102 and the gate driving circuits (such as the second gate driving circuits GOP-2) may be optionally arranged along the bevel edge of the display region AA in arrangement that the test circuit 102 is between the display region AA and the gate driving circuits. It should be understood that in other embodiments, the gate driving circuits (such as the second gate driving circuits GOP-2) may be arranged between the display region AA and the test circuit 102 according to the design requirements.

Please refer to FIG. 3, which is an equivalent circuit diagram of a test circuit unit 102a according to an embodiment of present disclosure. The test circuit unit 102a includes a plurality of switch devices ST, a plurality of control devices CT, a switch signal line SB that control on/off of the switch devices ST, a plurality of control signal lines SW that control on/off of the control devices CT, and a common source line BDL, wherein each of the data lines DL is connected to the common source line BDL through a switch device ST and a control device CT. During a test process, the switch signal line SB and a selected control signal line SW are at high potential level, such that the switch devices ST and the selected control device CT are turned on, allowing a test signal provided by the common source line BDL into the selected data line DL. After the test process is completed, the switch signal line SB is at low potential level and the switch devices ST are turned off to cut off the electrical connection between the test circuit unit 102a and the data lines DL, so as to prevent any interference noise generated by the test circuit unit 102a from affecting the display region AA. It should be understood that the number of switch devices, signal lines and the data lines DL that are connected to the test circuit unit 102a shown in FIG. 3 are only examples and should not be considered as a limitation to the disclosure. The actual design may be adjusted according to design requirements. The switch devices and control devices disclosed herein may be, for example, transistors or thin-film transistors, but are not limited thereto.

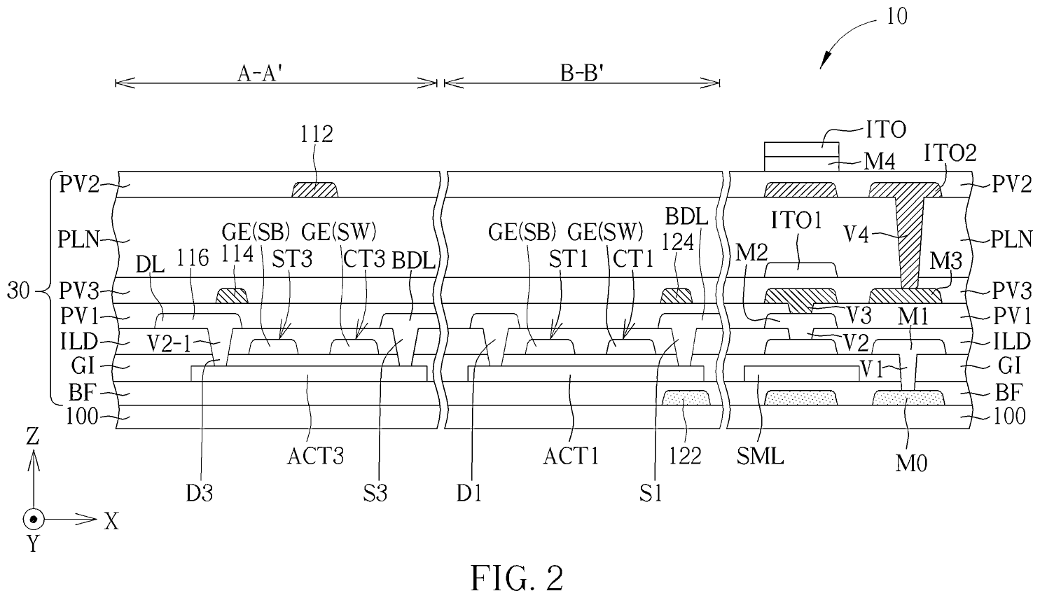

Please refer to FIG. 1, which is a schematic plan view of a portion of a panel 10, showing a layout of a test circuit unit 102a that includes a plurality of switch devices ST, a plurality of control devices CT, a switch signal line SB, a plurality of control signal lines SW, and a common source line BDL, a plurality of data lines DL, and a plurality of conductive components, local interconnection structures, and interlayer contacts to construct the circuit as shown in FIG. 3. The above circuit components are formed in at least a patterned semiconductor layer SML and a plurality of patterned conductive layers M0, M1, M2, M3, and ITO2 of a circuit layer 30 of the panel 10. In some embodiment, the semiconductor layers (such as the semiconductor layer ACT1, the semiconductor layer ACT2 and the semiconductor layer ACT3) of the switch devices ST and the control devices CT are formed in semiconductor layer SML. The gates GE of the switch devices ST and the control devices CT are formed in the conductive layer M1. The common source line BDL and the data lines DL are formed in the conductive layer M2. The switch signal line SB and the control signal line SW are formed in the conductive layer M1. The detailed description about the stacking structure of circuit layer 30 may be referred to FIG. 2 and the corresponding paragraphs. The semiconductor layer SML, the conductive layers M0, M1, M2, M3, and ITO2 are respectively located at different heights on the substrate 100 of the panel. That is, the minimum distances from these layers to the substrate 100 are different.

As shown in FIG. 1, the test circuit unit 102a may be divided into a left portion and a right portion by using the common source line BDL as the central axis. The switch devices ST, the control devices CT, the control signal lines SW, and the data lines DL may be divided into two groups that are arranged on the left and right sides of the common source line BDL and symmetrically to each other. As shown in FIG. 1, the switch signal line SB has a U-shape in the plan view, extending from the left portion of the test circuit unit 102a and bypassing the end of the common source line BDL to the right portion test circuit unit 102a. Overall, the test circuit unit 102a has a symmetrical layout.

In detail, the left portion of the test circuit unit 102a includes a first switch device ST1, a second switch device ST2 and a third switch device ST3 that are arranged along the Y direction. The left portion of the test circuit unit 102a further includes a first control device CT1, a second control device CT2 and a third control device CT3 that are also aligned along the Y direction and are respectively positioned between the first switch device ST1, the second switch device ST2 and the third switch device ST3 and the common source line BDL in the X direction. It should be understood that to simplify the drawings, only three switch devices and three control devices are exemplarily shown in FIG. 1 for elaborating the feature of the disclosure, and in other embodiments the numbers of the switch devices and three control devices may be adjusted according to design needs.

The first switch device ST1, the second switch device ST2, the third switch device ST3, the first control device CT1, the second control device CT2 and the third control device CT3 may be top-gate thin film transistors, where the first switch device ST1 and the first control device CT1 are formed in the same semiconductor layer ACT1. The gate GE of the first switch device ST1 is a portion of the switch signal line SB that overlaps the semiconductor layer ACT1. The drain D1 of the first switch device ST1 is electrically connected to one of the data lines DL through a first conductive component 112. The source S1 of the first control device CT1 is electrically connected to the common source line BDL. The gate GE of the first control device CT1 is electrically connected to one of the control signal lines SW. According to some embodiments of this disclosure, the first conductive component 112 is formed in the conductive layer ITO2, and crosses over the second switch device ST2, and is at least partially overlapped with the second switch device ST2. The gate GE, the switch signal line SB, and the control signal lines SW are formed in the conductive layer M1. The drain D1 of the first switch device ST1 and the source S1 of the first control device CT1 are formed in of the conductive layer M2.

Similarly, the second switch device ST2 and the second control device CT2 are formed in the same semiconductor layer ACT2. The gate GE of the second switch device ST2 is a portion of the switch signal line SB that overlaps the semiconductor layer ACT2. The drain D2 of the second switch device ST2 is electrically connected to another data line DL through a second conductive component 114. The source S2 of the second control device CT2 is electrically connected to the common source line BDL. The gate GE of the second control device CT2 is electrically connected to another control signal line SW through a fourth conductive component 124. According to some embodiments of this disclosure, the second conductive component 114 and the fourth conductive component 124 are both formed in the conductive layer M3, wherein the second conductive component 114 crosses over the third switch device ST3 and is at least partially overlapped with the third switch device ST3, and the fourth conductive component 124 crosses over the first control device CT1 and is at least partially overlapped with the first control device CT1. The drain D2 of the second switch device ST2 and the source S2 of the second control device CT2 are formed in the conductive layer M2.

The third switch device ST3 and the third control device CT3 are formed in the same semiconductor layer ACT3. The gate GE of the third switch device ST3 is a portion of the switch signal line SB that overlaps the semiconductor layer ACT3. The drain D3 of the third switch device ST3 is electrically connected to still another data line DL. The source S3 of the third control device CT3 is electrically connected to the common source line BDL. The gate GE of the third control device CT3 is electrically connected to still another control signal line SW through a third conductive component 122. According to some embodiments of this disclosure, the third conductive component 122 is formed in the conductive layer M0, and crosses below the second control device CT2, at least partially overlapped with the second control device CT2. The drain D3 of the third switch device ST3 and the source S3 of the third control device CT3 are formed in the conductive layer M2.

In some embodiments, the electrical interconnection in the vertical direction (the Z direction) between the different conductive layers may be achieved by interlayer contacts. For example, as shown in FIG. 1, the conductive layer M1 and the conductive layer M0 may be electrically connected through the contact V1. The conductive layer M2 and the conductive layer M1 may be electrically connected through the contact V2. The conductive layer M2 and the semiconductor layer SML may be electrically connected through the contact V2-1. The conductive layer M3 and the conductive layer M2 may be electrically connected through the contact V. The conductive layer ITO2 and the conductive layer M3 may be electrically connected through the contact V4.

In some embodiments, the test circuit unit 102a further includes local interconnection structures to electrically connect the conductive portions to a farther conductive layer. For example, as shown in FIG. 1, the two end portions of the first conductive component 112 are respectively electrically connected to the drain D1 of the first switch device ST1 and the data line DL through a local interconnection structure formed by the conductive layer M3 and a contact V3. The two end portions of the fourth conductive component 124 are respectively electrically connected to the gate GE of the second control device CT2 and the control signal line SW through a local interconnection structure formed by the conductive layer M2 and a contact V2. The local interconnect structures may be formed by any suitable conductive layers according to design needs.

It should be understood that since the right portion of the test circuit unit 102a is mirror symmetrical with the left portion of the test circuit unit 102a, the layout design of the right portion may refer to the above description of the left portion, and will not be repeated herein.

Please refer to FIG. 2, which shows some schematic cross-sectional views of different positions of a panel 10. The left portion of FIG. 2 is a cross-sectional view of the third switch device ST3 and the third control device CT3 along the line AA′ shown in FIG. 1. The middle portion of FIG. 2 is a cross-sectional view of the first switch device ST1 and the first control device CT1 along the line BB′ shown in FIG. 1. The right portion of FIG. 2 is a cross-sectional view of another portion to illustrate the connection structures (such as contacts) used to electrically connect other conductive layers to facilitate understanding of the layout design of the test circuit unit 102a.

As shown in FIG. 2, the panel 10 includes a substrate 100 and a circuit layer 30 arranged on the substrate 100. The substrate 100 may be a hard substrate or a flexible substrate, and the materials of substrate 100 may include glass, ceramics, quartz, sapphire, polyimide (PI), polycarbonate (PC), polyethylene terephthalate (PET), or a combination thereof, but is not limited thereto. The circuit layer 30 is a stack structure. For example, the circuit layer 30 may include, from bottom to top, a conductive layer M0, an insulating layer BF, a semiconductor layer SML, a gate insulating layer GI, a conductive layer M1, an insulating layer ILD, a conductive layer M2, an insulating layer PV1, a conductive layer M3, an insulating layer PV3, a conductive layer ITO1, an insulating layer PLN, a conductive layer ITO2, and an insulating layer PV2. In other embodiments, the circuit layer 30 may include other suitable stacked structures. In some embodiments, other conductive layers may be disposed on the circuit layer 30, such as the conductive layer M4 and the conductive layer ITO that may be used to form routing traces or to electrically connect the components (such as light emitting diodes) on the circuit layer 30.

The circuit layer 30 may further include interlayer contacts that extend vertically through the insulating layers to electrically connect different conductive layers in the vertical direction (the Z direction). For example, the circuit layer 30 may include a contact V1 that extends through the gate insulation layer GI and the insulating layer BF to electrically connect the conductive layer M1 and the conductive layer M0, a contact V2 that extends through the insulating layer ILD to electrically connect the conductive layer M2 and the conductive layer M1, a contact V2-1 that extends through the insulating layer ILD and the gate insulating layer GI to electrically connect the conductive layer M2 and the semiconductor layer SML, a contact V3 that extends through the insulating layer PV1 to electrically connect the conductive layer M3 and the conductive layer M2, and a contact V4 that extends through the insulating layer PLN and the insulating layer PV3 to electrically connect the conductive layer ITO2 and the conductive layer M3. The design of the conductive layers and the contacts shown in FIG. 2 is only an example, and may be adjusted according design needs.

The insulating layer BF, the gate insulating layer GI, the insulating layer ILD, the insulating layer PV1, the insulating layer PV3, the insulating layer PLN and the insulating layer PV2 may be a single layer or may consist of multiple layers, respectively. The above layers may respectively include an inorganic dielectric material such as silicon nitride (SiNx), silicon oxide (SiOx), silicon nitride (SiON), or an organic dielectric material, such as acrylic resin (acrylic resin) or other suitable materials, or a combination thereof, but is not limited thereto.

The semiconductor-layer SML may include amorphous silicon, low-temperature polycrystalline silicon (LTPS), low-temperature polycrystalline oxide (LTPO), or metal oxide semiconductor such as indium gallium zinc oxide (IGZO), indium gallium tin oxide (IGTO), or indium gallium zinc tin oxide (IGTZO), but is not limited thereto.

The conductive layer M0, the conductive layer M1, the conductive layer M2, the conductive layer M3, the conductive layer M4, the conductive layer ITO1, the conductive layer ITO2 and the conductive layer ITO may respectively include a metal conductive material, a transparent conductive material or any other suitable conductive materials. The metal conductive material may include aluminum (Al), copper (Cu), silver (Ag), chromium (Cr), titanium (Ti), molybdenum (Mo), nickel (Ni), rhodium (Mc), any other suitable metal materials, a combination or an alloys of the above, but is not limited thereto. The transparent conductive material may include indium tin oxide (ITO), indium zinc oxide (IGZO) or zinc alumina oxide (AZO), but is not limited thereto.

The test circuit (or test circuit unit) provided in the disclosure as described above uses different conductive layers to form conductive components and/or local interconnection structures to construct the electrical interconnections of the test circuit (or test circuit unit), so that the layout space efficiency of the test circuit (or test circuit unit) may be improved. In this way, a test circuit that may perform a full test to the entire pixel array of the display region may be arranged within a limited area of the peripheral region of the panel.

In some embodiments of the present disclosure, as shown in FIG. 4, the arrangement of the second gate driving circuits GOP-2 near the bevel edge of the display region AA may be adjusted to shorten the length L2 of the second gate driving circuit GOP-2. In this way, the width Wb of the peripheral region PR near the bevel edge of the display region AA may be approximately equal to the width Wa of the peripheral region PR near the flat edge of the display region AA even when the test circuit 102 and the second gate driving circuits GOP-2 are disposed in the peripheral region PR near the bevel edge, so that a uniform bezel width around the panel may be achieved.

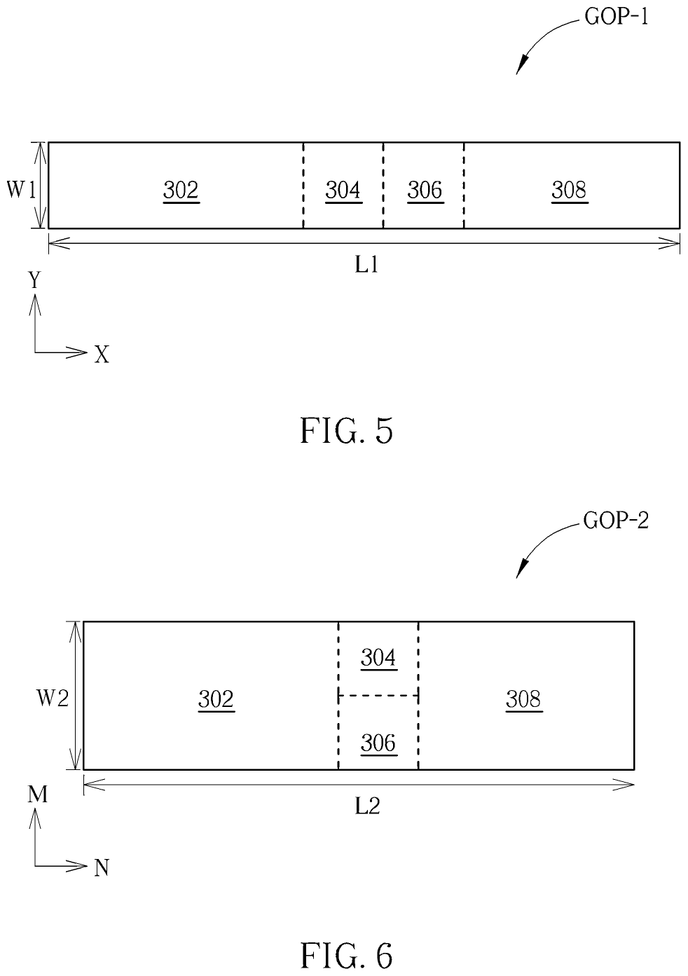

Please refer to FIG. 4, FIG. 5 and FIG. 6. FIG. 5 is a schematic diagram showing an arrangement of circuit blocks of a first gate driving circuit GOP-1 according to an embodiment of the present disclosure. FIG. 6 is a schematic diagram showing an arrangement of circuit blocks of a second gate driving circuit GOP-2 according to an embodiment of the present disclosure. A shown in FIG. 4, the first gate driving circuits GOP-1 are arranged along the Y direction and next to the edge of the display region AA that the scan lines GL extend out from the display region AA. The second gate driving circuits GOP-2 are arranged along the M direction and next to the bevel edge of the display region AA, wherein the bevel edge is approximately parallel to the M direction. The first gate driving circuits GOP-1 and the second gate driving circuits GOP-2 respectively include multiple circuit blocks, such as a shift register circuit block 302, an output circuit block 304, a charge release circuit block 306, and a buffer circuit block 308. As shown in FIG. 5, in the first gate driving circuit GOP-1, the shift register circuit block 302, the output circuit block 304, the charge release circuit block 306 and the buffer circuit block 308 are arranged in order along the X direction, and the first gate driving circuit GOP-1 may have a length L1 and a width W1. As shown in FIG. 6, in the second gate driving circuit GOP-2, the output circuit block 304 and the charge release circuit block 306 are arranged along the M direction and are between the shift register circuit block 302 and the buffer circuit block 308 along the N direction. The second gate driving circuit GOP-2 may have a length L2 and a width W2. The length L2 is smaller than the length L1, and the width W2 is larger than the width W1.

In some embodiments of the present disclosure, the test circuit 102 may be disposed in a cut-off region of the panel 10, and may be removed with the cut-off region after the test process is completed. In this way, the bezel width of the product may be further reduced since the peripheral region PR of the product does not include the area occupied by the test circuit 102.

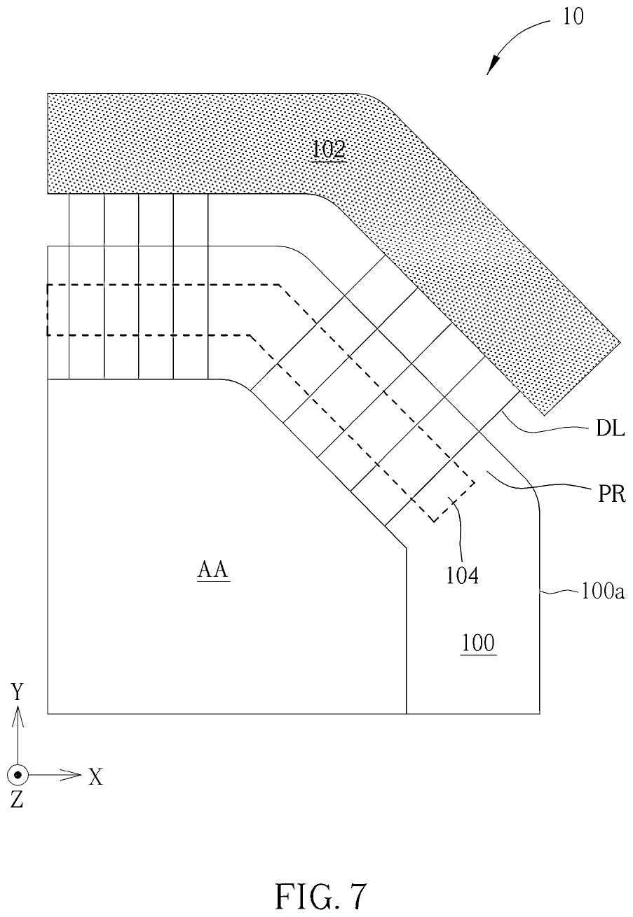

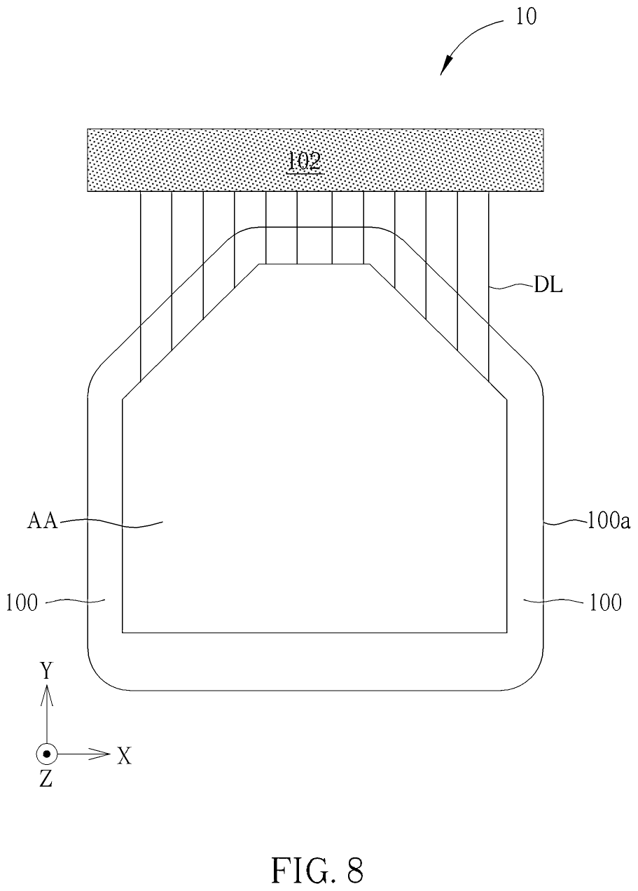

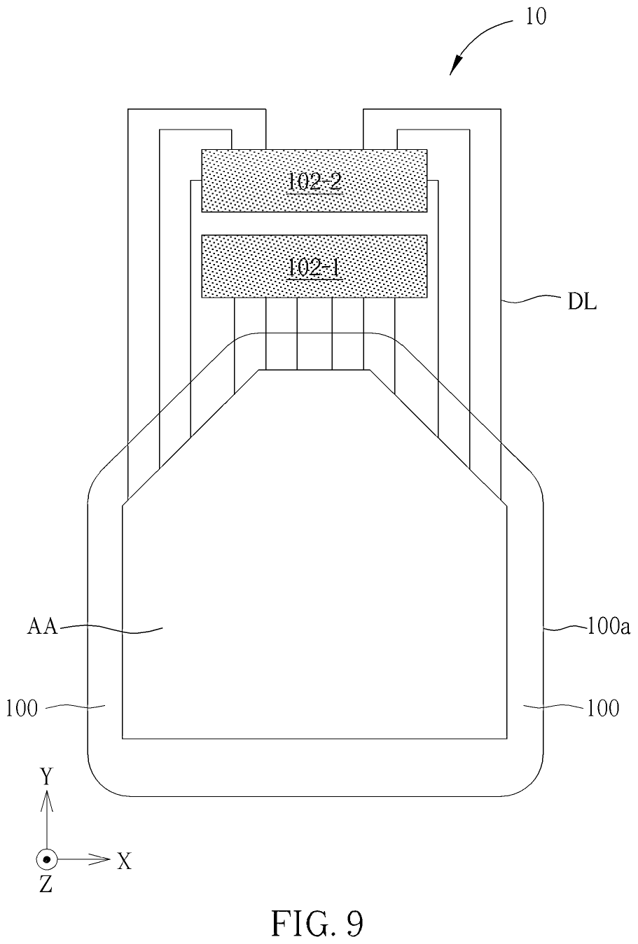

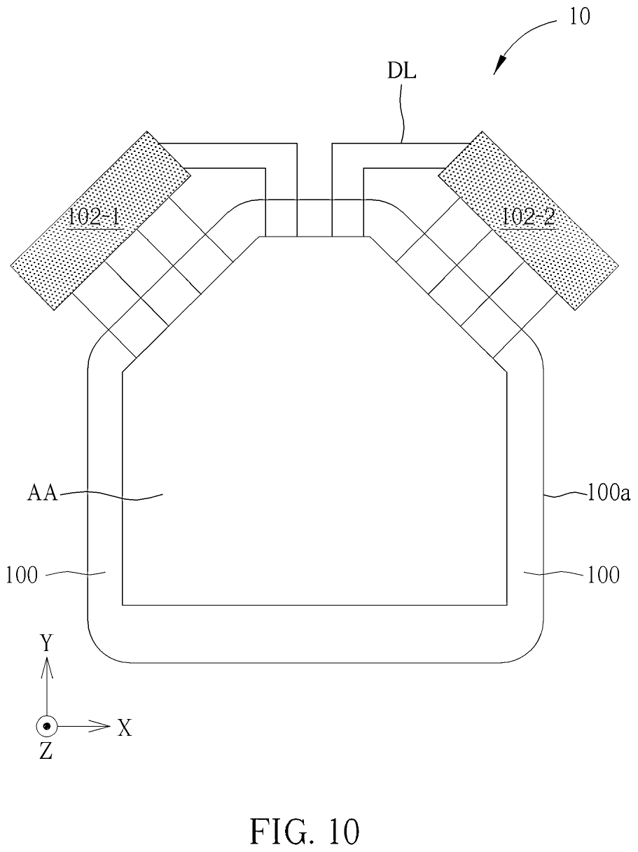

For example, please refer to FIG. 7, FIG. 8, FIG. 9 and FIG. 10, which are some embodiments in which the test circuit 102 is disposed in the cut-off region of the panel 10. The cut-off region is the region outside the cutting edge 100a that does not include the display region AA. In the embodiment shown in FIG. 7, the cutting edge 100a has a flat edge portion and a bevel edge portion in accordance with the shape of the display region AA, and the test circuit 102 is arranged in the cut-off region and continuously along the flat edge and the bevel edge of the cutting edge 100a. The data lines DL extending out from the bevel edge of the display region AA may bend to be parallel to each other along the extending direction of the bevel edge of the display region AA, so as to smoothly connect to the test circuit 102. In the embodiment shown in FIG. 8, the test circuit 102 is arranged in the cut-off region and extends to a length along a direction parallel to the flat edge portion of the cutting edge 100a, wherein the length of the test circuit 102 is sufficient to connect with each of the data lines DL that extend out from the flat and bevel edges of the display region AA and are parallel to each other. In the embodiment shown in FIG. 9, a test circuit 102-1 arranged in the cut-off region and extends along a direction parallel to the flat edge portion of the cutting edge 100a, and another test circuit 102-2 is arranged in the cut-off region and parallel to a side of the test circuit 102-1 opposite to the display region AA. The test circuit 102-1 is electrically connected with the data lines DL extending from the flat edge of the display region AA. The test circuit 102-2 is electrically connected with the data lines DL extending from the bevel edges of the display region AA. The data lines DL extending from the bevel edges the display region AA may bend to connect to the test circuit 102-2 smoothly. In the embodiment shown in FIG. 10, a test circuit 102-1 and another test circuit 102-2 may be arranged in the cut-off region and respectively near different bevel edge portions of the cutting edge 100a in an orientation parallel to the bevel edge portions. The test circuit 102-1 is electrically connected with the data lines DL extending from the bevel edge of the display region AA that corresponding to the test circuit 102-1. The test circuit 102-2 is electrically connected with the data lines DL extending from the bevel edge of the display region AA that corresponding to the test circuit 102-2. Some data lines DL extending from the flat edge of the display region AA may be electrically connected to the test circuit 102-1 and the other data lines DL extending from the flat edge of the display region AA may be electrically connected to the test circuit 102-2. The data lines DL extending from the flat edge of the display region AA may bend to connect to the test circuit 102-1 or the test circuit 102-2 smoothly. In some embodiments, as shown in FIG. 7, an electrostatic protection circuit 104 may be arranged in the portion of the peripheral region PR where the data lines DL extend through to connect the test circuits. The electrostatic protection circuit may protect the display region AA from damages due to static discharges entering from the line ends of the data lines DL exposed at the cutting edge 100a. In some embodiments, an insulating material may be applied to the cutting edge 100a to electrically isolate the line ends of the data lines DL from the outside.

In conclusion, the present disclosure provide an electronic device including a panel having a test circuit that uses different conductive layers to construct the electrical interconnections of the test circuit, so that the layout space efficiency of the test circuit may be improved. In this way, a test circuit capable to perform a full test to the entire pixel array of the display region may be arranged within a limited area of the peripheral region of the panel. Furthermore, the present disclosure also provide embodiments in which the test circuit and the gate driving circuits are simultaneously arranged in the bevel region of the peripheral region, wherein the space utilization may be optimized by rearranging the positions of the circuit blocks in each of the gate driving circuits to reduce the width of the gate driving circuits, so that the width of the bevel region of the peripheral region may be reduced to fulfill the design need of narrow bezel products.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device comprising a panel, wherein the panel comprises:
a substrate;
a plurality of signal lines arranged on the substrate; and
a test circuit arranged on the substrate and comprising:
a first switch device and a second switch device electrically connected to a same switch signal line;
a first conductive component electrically connected between the first switch device and one of the signal lines; and
a second conductive component electrically connected between the second switch device and another one of the signal lines, wherein the first conductive component and the second switch device are at least partially overlapped.

2. The electronic device according to claim 1, wherein a minimum distance from the first conductive component to the substrate is different from a minimum distance from the second conductive component to the substrate.

3. The electronic device according to claim 1, wherein a gate of the first switch device, a gate of the second switch device and the switch signal line are formed in a first conductive layer, the signal lines are formed in a second conductive layer, the second conductive component is formed in a third conductive layer, and the first conductive component is formed in a fourth conductive layer.

4. The electronic device according to claim 3, wherein a minimum distance from the first conductive layer to the substrate, a minimum distance from the second conductive layer to the substrate, a minimum distance from the third conductive layer to the substrate, and a minimum distance from the fourth conductive layer to the substrate are different from each other.

5. The electronic device according to claim 3, wherein in a cross-sectional view, the second conductive layer is above the first conductive layer, the third conductive layer is above the second conductive layer, and the fourth conductive layer is above the third conductive layer.

6. The electronic device according to claim 1, wherein the test circuit further comprises:
a third switch device, electrically connected to the same switch signal line with the first switch device and the second switch device, and electrically connected to still another one of the signal lines.

7. The electronic device according to claim 6, wherein the first switch device, the second switch device and the third switch device are arranged along a direction parallel to an extending direction of the signal lines.

8. The electronic device according to claim 6, wherein the test circuit further comprises:
a first control device, a second control device and a third control device respectively electrically connected to the first switch device, the second switch device, and the third switch device; and
a plurality of control signal lines respectively electrically connected to the first control device, the second control device and the third control device.

9. The electronic device according to claim 8, wherein the test circuit further comprises a third conductive component and a fourth conductive component, the third conductive component being electrically connected between one of the control signal lines and the third control device, the fourth conductive component being electrically connected between another one of the control signal lines and the second control device, wherein the third conductive component and the second control device are at least partially overlapped.

10. The electronic device according to claim 9, wherein a minimum distance from the third conductive component to the substrate is different from a minimum distance from the fourth conductive component to the substrate.

11. The electronic device according to claim 9, wherein the second conductive component and the fourth conductive component are formed in a same conductive layer.

12. The electronic device according to claim 9, in a cross-sectional view, the third conductive component is between the substrate and a semiconductor layer of the third control device.

13. The electronic device according to claim 8, wherein the test circuit further comprises a common source line electrically connected to the first control device, the second control device, and the third control device, wherein an extending direction of the common source line is parallel to an extending direction of the signal lines.

14. The electronic device according to claim 13, wherein the common source line and the signal lines are formed in a same conductive layer.

15. The electronic device according to claim 13, wherein in a plan view, the signal lines are arranged between the switch signal line and the common source line.

16. The electronic device according to claim 13, wherein in a plan view, the switch signal line has a U-shape, and the common source line is located in a middle of the U-shape.

17. The electronic device according to claim 13, wherein the test circuit comprises a symmetrical structure with the common source line as a central axis.

18. The electronic device according to claim 1, further comprising:
a plurality of first gate driving circuits disposed on the substrate and being arranged along a first direction;
a plurality of second gate driving circuits disposed on the substrate and being arranged along a second direction, wherein the first direction and the second direction are different.

19. The electronic device according to claim 18, wherein the first gate driving circuits respectively comprise a shift register circuit block, an output circuit block, a charge release circuit block, and a buffer circuit block arranged sequentially along a third party direction.

20. The electronic device according to claim 18, wherein the second gate driving circuits respectively comprise a shift register circuit block, an output circuit block, a charge release circuit block, and a buffer circuit block, wherein the output circuit block and the charge release circuit block are disposed between the shift register circuit block and the buffer circuit block, the output circuit block and the charge release circuit block are arranged along the second direction, the shift register circuit block and the buffer circuit block are arranged along a fourth direction, and the second direction and the fourth direction are different.
